(19) United States
(12) Patent Application Publication
(10) Pub. No.: US 2024/0103442 A1
(43) Pub. Date: Mar. 28, 2024

(54) SUPPORT MEMBER FOR SUPPORTING A WAFER DURING A HEAT TREATMENT

(71) Applicant: PATEK PHILIPPE SA GENEVE, Genève (CH)

(72) Inventor: Sylvain JEANNERET, Colombier (CH)

(21) Appl. No.: 18/533,303

(22) Filed: Dec. 8, 2023

Related U.S. Application Data
(62) Division of application No. 16/980,126, filed on Sep. 11, 2020, now Pat. No. 11,880,165.

(30) Foreign Application Priority Data
Mar. 20, 2018 (EP) 18162729.0

(51) Int. Cl. G04B 17/06; C23C 14/08; C23C 16/40; G04B 17/22; G04D 3/00

(52) U.S. Cl. CPC G04B 17/066; C23C 14/08; C23C 16/401; G04B 17/22; G04B 17/227; G04D 3/00

(57) ABSTRACT

Disclosed is a support member for supporting a wafer during a heat treatment of the wafer. The support member includes a support plate and spacers and retaining elements carried by the support plate. The spacers serve to maintain a gap between the support plate and the wafer. The retaining elements serve to prevent the wafer from moving horizontally. The support plate may be made of silicon, quartz or silicon carbide. The spacers and the retaining elements may be fixed to the support plate by bayonet-type connections.

### CROSS REFERENCE TO RELATED APPLICATIONS

This application is a Divisional of application Ser. No. 16/980,126, filed on Sep. 11, 2020, which is the National Phase under 35 U.S.C. § 371 of International Application No. PCT/IB2019/052198, filed on Mar. 19, 2019, which claims the benefit under 35 U.S.C. § 119(a) to Patent Application No. 18162729.0, filed in Europe on Mar. 20, 2018, all of which are hereby expressly incorporated by reference into the present application.

### BACKGROUND OF THE INVENTION

### Field of the Invention

The present invention relates to a support member for supporting a wafer during a heat treatment of the wafer.

### Description of the Related Art

Methods for manufacturing silicon timepiece components have been described, notably, in documents EP 0732635, EP 1422436, EP 2215531 and EP 3181938.

### SUMMARY OF THE INVENTION

The present invention aims to propose a method for manufacturing high quality silicon timepiece components.

For this purpose, the present invention proposes a support member which facilitates the implementation of a heat treatment method and more generally the implementation of a heat treatment of a wafer.

### BRIEF DESCRIPTION OF THE DRAWINGS

Other characteristics and advantages of the present invention will appear when reading the following detailed description made with reference to the appended drawings in which:

FIGS. 1 to 11 schematically show successive steps of a method according to a particular embodiment of the invention;

FIGS. 12 and 13 are respectively a perspective view and a profile view of a support member used in the method according to the particular embodiment of the invention to support a silicon wafer during a thermal oxidation treatment of the latter;

FIGS. 14 and 15 schematically show a step of the method according to the particular embodiment of the invention, in which an etched silicon wafer is released from a composite substrate;

FIG. 16 shows a composite substrate from which a method according to another embodiment of the invention can be carried out.

### DESCRIPTION OF THE PREFERRED EMBODIMENTS

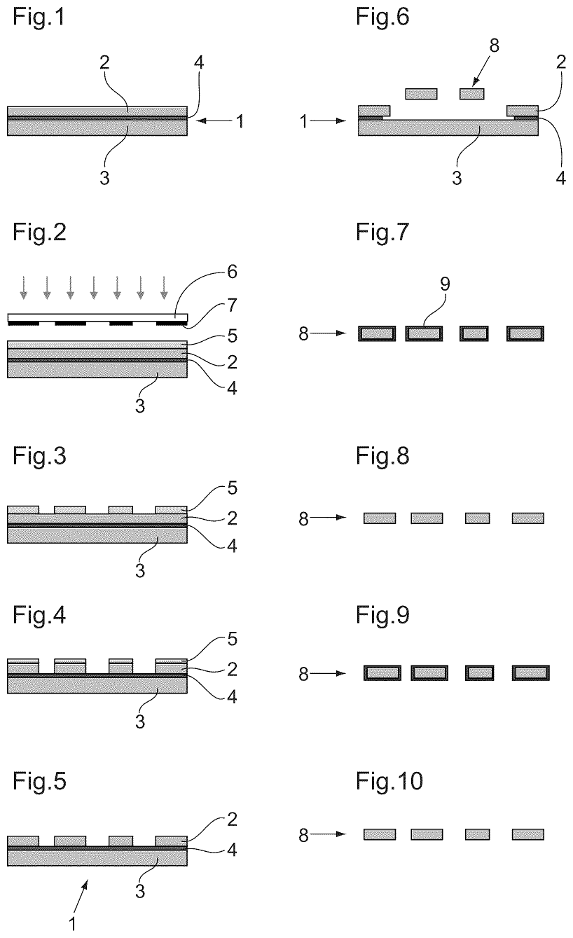

A method for manufacturing silicon timepiece components, in particular for wristwatches, comprises the successive steps illustrated in FIGS. 1 to 11, according to a particular embodiment of the invention.

In a first step (FIG. 1), a silicon-on-insulator (SOI) type substrate 1 is provided. The substrate 1 comprises an upper silicon layer 2, a lower silicon layer 3 and, in between, an intermediate silicon oxide layer 4. The silicon is monocrystalline, polycrystalline or amorphous. It can be doped or undoped. The thickness of the upper silicon layer 2 is chosen according to the thickness of the components to be produced. The lower silicon layer 3 serves to give the substrate 1 sufficient rigidity to facilitate its handling and the implementation of the operations that will be described below.

In a second step (FIG. 2), a photoresist layer 5 is deposited on the upper silicon layer 2 and this layer 5 is structured by photolithography. More precisely, the photoresist layer 5 is exposed to ultraviolet rays through a mask 6, typically made of glass or quartz, bearing a structure 7 to be transferred, typically made of chromium. Then the photoresist layer 5 is developed and cured (FIG. 3). At the end of these operations, the photoresist layer 5 has the same shape as the structure 7 and in turn constitutes a mask, the said shape corresponding to that of a batch of timepiece components to be manufactured.

In a subsequent step (FIG. 4), the upper silicon layer 2 is etched through the photoresist mask 5 by deep reactive ion etching (DRIE) in order to form the timepiece components in this layer 2. The etching is stopped by the intermediate silicon oxide layer 4, thus allowing to define a precise thickness for the timepiece components. The etching parameters can be adjusted according to the components, to obtain particular characteristics in terms of roughness or flank angle, for example. The timepiece components formed in the upper silicon layer 2 are preferably identical but could alternatively be divided into several groups, each group corresponding to a type of component. For example, the timepiece components include at least one of the following types of components: hairsprings, anchors, wheels, in particular escapement wheels, hands, rockers, levers, springs, balances, or parts of such components. The method according to the invention is particularly suitable for regulating organ components and more generally for timepiece movement components requiring low mass and/or low inertia.

The photoresist mask 5 is then removed by chemical etching or plasma etching (FIG. 5).

In a subsequent step (FIG. 6), a wafer 8 formed by at least all or part of the etched, upper silicon layer 2 is released from the substrate 1 in a manner that will be described later. This wafer 8 contains a basic structure and the timepiece components attached to the basic structure by material bridges left during etching.

The wafer 8 is then placed into an oxidation furnace to be subjected to a heat treatment, typically between 600° C. and 1300° C., oxidizing the entire outer surface of the timepiece components (FIG. 7). The silicon oxide (SiO2) layer 9 which then covers the wafer 8 and in particular the timepiece components is formed by consuming silicon from the wafer 8, which causes the interface between the silicon and the silicon oxide to recede and attenuates the surface defects of the silicon. By subsequently removing the silicon oxide (FIG. 8), by wet etching, vapor etching or dry etching, timepiece components with a good surface finish are obtained. In particular, the flank roughness due to the DRIE etching and the surface crystal defects are greatly reduced.

At this stage of the method, it is possible to measure physical characteristics of the timepiece components or of some of them, in particular their dimensions. Thanks to the previous oxidation-deoxidation step, these physical characteristics are well defined and their measurement can therefore be precise, since it is not disturbed by surface defects. In the case of hairsprings, their stiffness can be determined. For a given hairspring, the stiffness can be determined by coupling the hairspring, while it is still attached to the wafer 8 or detached from the wafer 8, to a balance of predetermined inertia, by measuring the frequency of the balance-hairspring assembly and deducing from this measurement, by calculation, the stiffness of the hairspring. More particularly, the method described in patent application EP 3181938 can be implemented, i.e. determining the stiffness of the hairsprings, calculating a material thickness to be removed from the hairsprings to obtain a desired stiffness, and then removing this material thickness to obtain hairsprings of the desired stiffness. To remove this material thickness, the wafer 8 and its timepiece components can be thermally oxidized (FIG. 9) and then deoxidized (FIG. 10) in the same way as described above with reference to FIGS. 7 and 8. The operations of determining the stiffness, calculating the thickness to be removed and removing this thickness by oxidation—deoxidation can be repeated if necessary to refine the dimensional accuracy of the hairsprings.

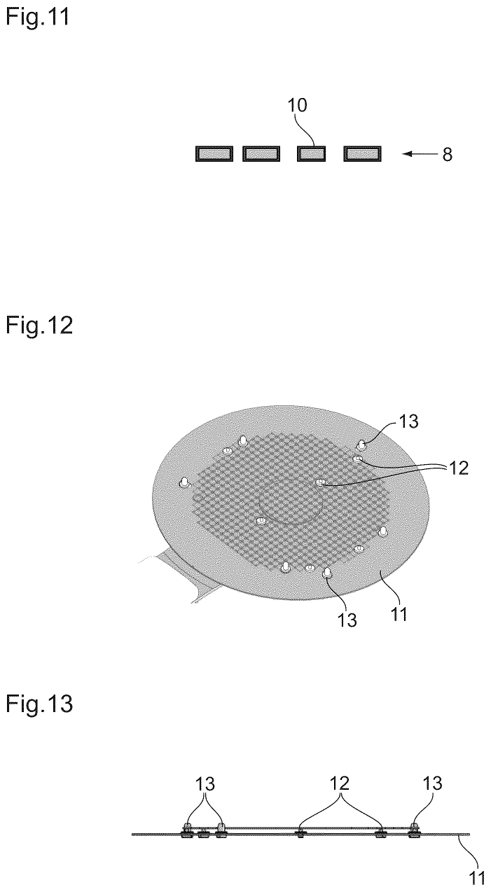

In yet another step of the method (FIG. 11), a silicon oxide (SiO2) layer 10 is formed on the wafer 8 and its timepiece components, for example by thermal oxidation or by chemical or physical vapor deposition (CVD, PVD). This silicon oxide layer 10, which coats the timepiece components, increases their mechanical strength. In the case of a hairspring, the silicon oxide layer 10 has a thickness that enables it to compensate for the temperature-dependent variations in the modulus of elasticity of the silicon core as well as the temperature-dependent variations in the moment of inertia of the balance that the hairspring is intended to equip, so that the frequency of the balance-hairspring oscillator is insensitive to temperature, as described in patents EP 1422436 and EP 2215531.

In a final step, the timepiece components are detached from the basic structure of the wafer 8.

During the oxidation steps (FIGS. 7 and 9 and, if applicable, FIG. 11), the wafer 8 is preferably supported horizontally by a support plate 11 as shown in FIGS. 12 and 13, which can be handled manually or by a robot. This support plate 11 is made of a material compatible with the oxidation treatment, e.g. quartz, silicon or silicon carbide. In order to allow homogeneous oxidation of the wafer 8, the wafer 8 is raised with respect to the support plate 11 by spacers 12 which support the wafer 8 in areas that do not contain any components (especially between the components). The wafer 8 is prevented from moving horizontally by retaining elements 13 which cooperate with the peripheral edge of the wafer 8. The spacers 12 and the retaining elements 13 are generally cylindrical in shape. They are fixed relative to the support plate 11, e.g. attached to the support plate 11 by bayonet-type connections. They are made, for example, of quartz or silicon carbide, and may be made of the same material or of different materials. In a preferred embodiment, the support plate 11 is made of silicon and the spacers and retaining elements 12, 13 are made of quartz. Such a support plate 11 with its spacers 12 and retaining elements 13 can also be used during the step in FIG. 11 when the latter consists of a CVD or PVD deposition operation.

Preferably, during the oxidation treatment of FIG. 9, the wafer 8 is placed on the support plate 11 in an inverted position with respect to the oxidation treatment of FIG. 7. Likewise, during the oxidation or deposition treatment of FIG. 11, the wafer 8 is placed on the support plate 11 in an inverted position with respect to the oxidation treatment of FIG. 9. This prevents or at least limits permanent deformation of the timepiece components under the effect of gravity and heat.

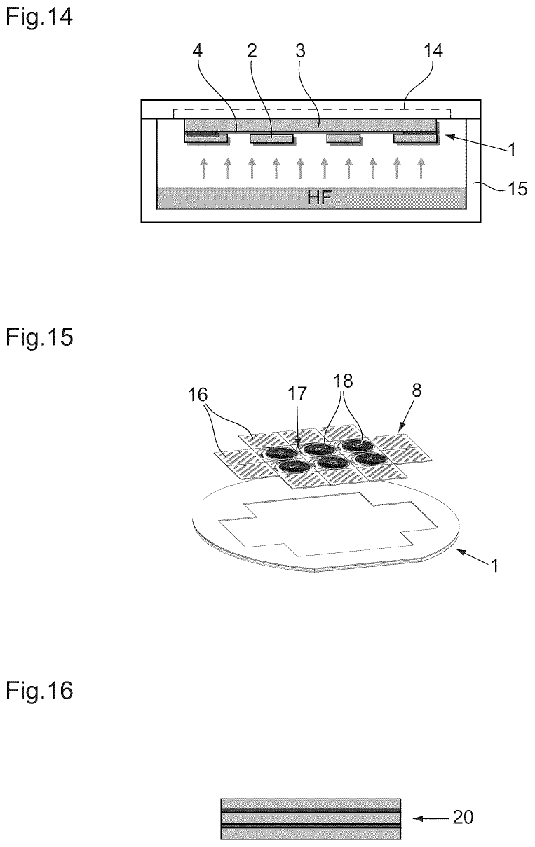

The step of releasing the wafer 8 from the substrate 1 (FIG. 6) can be carried out by removing the entire lower silicon layer 3 and the entire intermediate silicon oxide layer 4 by chemical or plasma etching. Alternatively, the lower silicon layer 3 and the intermediate silicon oxide layer 4 can be removed only at the back of the components or of the component groups, whereby the wafer 8 retains some of these layers 3, 4. However, these operations are time-consuming and expensive. In the present invention, preferably, the wafer 8 is formed by a part of the upper silicon layer 2 and its release from the substrate 1 is carried out in the manner set forth below and illustrated in FIGS. 14 and 15.

The etched substrate 1 as shown in FIG. 5 is fixed against a heating element 14 in a closed chamber 15 (FIG. 14), with the upper silicon layer 2 facing downwards and the lower silicon layer 3, thus facing upwards, being against the heating element 14. The method of fixing the substrate 1 against the heating element 14 can be electrostatic (by applying an electric field) or mechanical. A solution of hydrofluoric acid (HF) is added into the chamber 15, out of contact with the substrate 1. The vapors of the hydrofluoric acid which then saturate the inside of chamber 15 etch the intermediate silicon oxide layer 4, without etching the silicon. The heating element 14, which is temperature-regulated, prevents condensation of the water produced by the reaction between the hydrofluoric acid and the silicon oxide, which condensation would cause the part to be released to stick to the rest of the substrate 1.

The part to be released, i.e. the wafer 8, is defined beforehand by a groove made during the etching of the upper silicon layer 2 and which forms the peripheral edge of the wafer 8. During this same etching of the upper silicon layer 2, openings 16, e.g. in the form of hatching as shown in FIG. 15, are etched in the wafer 8 around a central area 17 containing the components. These openings 16 allow the passage of the hydrofluoric acid vapor.

FIG. 15 shows an example of wafer 8 with a shape consisting of rectangular or square parts. Other shapes can of course be considered, for example the circular shape. In FIG. 15 can be seen the timepiece components 18, here consisting of hairsprings, carried by the wafer 8. These timepiece components have been represented in a reduced number compared to their real number, in order to facilitate the reading of the drawing.

The timepiece components manufactured by the method according to the invention can have very precise dimensions and good surface finishes which will improve the precision of operation and the performance of the mechanisms that will use them.

Modifications of the method according to the invention as described above are of course possible.

For example, although the two oxidation-deoxidation steps (FIGS. 7, 8 and FIGS. 9, 10) to respectively improve the surface finish of the timepiece components and adjust their stiffness (in the case of hairsprings) are particularly advantageous, only one could be provided, both to improve the surface finish and to adjust the stiffness, which would be preceded by a step of determination of the stiffness.

Alternatively, one could start from a double or triple SOI substrate, or even more, i.e. a substrate comprising more than two silicon layers separated by intermediate silicon oxide layers, such as the substrate 20 shown in FIG. 16, and etch the timepiece components in a group of upper layers which would then be released from the substrate. The timepiece components would then have a composite structure comprising one or more intermediate silicon oxide layers.

The photoresist mask 5 that is used to structure the upper silicon layer 2 (FIG. 3) could be replaced by a silicon oxide mask. One could also associate a photoresist mask and a silicon oxide mask to produce multi-level timepiece components by etching in the upper silicon layer or in a group of upper layers.

In other variants, the substrate could be etched from its two sides.

The silicon oxide layer(s) serving to stop the etching could be reinforced by one or more layers of the parylene type.

Finally, the present invention does not exclude the use of one or more metallic layers to stop the etching.

1. A support member for supporting a wafer during a heat treatment of the wafer, the support member comprising a support plate and spacers and retaining elements carried by the support plate, the spacers serving to maintain a gap between the support plate and the wafer, the retaining elements serving to prevent the wafer from moving horizontally.

2. The support member according to claim 1, wherein the support plate is made of silicon, quartz or silicon carbide.

3. The support member according to claim 1, wherein the spacers and the retaining elements are made of quartz or silicon carbide.

4. The support member according to claim 2, wherein the spacers and the retaining elements are made of quartz or silicon carbide.

5. The support member according to claim 1, wherein the spacers and the retaining elements are fixed to the support plate by bayonet-type connections.

6. The support member according to claim 2, wherein the spacers and the retaining elements are fixed to the support plate by bayonet-type connections.

7. The support member according to claim 3, wherein the spacers and the retaining elements are fixed to the support plate by bayonet-type connections.
